(19) United States
(12) Patent Application Publication
(10) Pub. No.: US 2025/0053058 A1
(43) Pub. Date: Feb. 13, 2025

(54) BACKPLANES FOR SEGMENTED ELECTRO-OPTIC DISPLAYS AND METHODS OF MANUFACTURING SAME

(71) Applicant: E INK CORPORATION, Billerica, MA (US)

(72) Inventor: Bryan DUNN, Medford, MA (US)

(21) Appl. No.: 18/779,900

(22) Filed: Jul. 22, 2024

Related U.S. Application Data
(60) Provisional application No. 63/531,337, filed on Aug. 8, 2023.

(51) Int. Cl. G02F 1/1676; G02F 1/167; G02F 1/16757

(52) U.S. Cl. CPC G02F 1/1676; G02F 1/167; G02F 1/16757

(57) ABSTRACT

Method for manufacturing segmented electro-optic display backplanes includes (a) providing a laminate comprising an insulating layer having opposite first and second surfaces and a conductive metal layer having opposite first and second surfaces (the insulating layer second surface is superposed on the conductive metal layer first surface); (b) applying laser energy from a first laser source passing through the insulating layer onto selected portions of conductive metal layer first surface to cause adjacent portions of the insulating layer to be pyrolyzed to form conductive carbon regions; (c) applying laser energy from a second laser source on the insulating layer first surface to pyrolyze selected portions thereof into conductive carbon segments electrically isolated from each other by other portions of the insulating layer. The conductive carbon regions in the insulating layer form vias between each of the conductive carbon segments and one of the selected portions of the conductive metal layer.

### CROSS-REFERENCE TO RELATED APPLICATIONS

This application claims priority from U.S. Provisional Patent Application No. 63/531,337 filed on 8 Aug. 2023 entitled BACKPLANES FOR SEGMENTED ELECTRO-OPTIC DISPLAYS AND METHODS OF MANUFACTURING SAME, which is hereby incorporated by reference in its entirety.

### BACKGROUND

The present application relates to backplanes for segmented electro-optic displays and methods of manufacture. Such backplanes are particularly, but not exclusively, intended for use with displays comprising encapsulated electrophoretic media. The backplanes can also be used with various other types of electro-optic media that are “solid” in the sense that they have solid external surfaces, although the media may, and often do, have internal cavities that contain a fluid (either liquid or gas). Such “solid electro-optic displays” include encapsulated electrophoretic displays, encapsulated liquid crystal displays, and other types of displays discussed below.

Electro-optic displays comprise a layer of electro-optic material, a term that is used herein in its conventional meaning in the imaging art to refer to a material having at least first and second display states differing in at least one optical property, the material being changed from its first to its second display state by application of an electric field to the material. Although the optical property is typically color perceptible to the human eye, it may be another optical property, such as optical transmission, reflectance, luminescence, or, in the case of displays intended for machine reading, pseudo-color in the sense of a change in reflectance of electromagnetic wavelengths outside the visible range.

The terms “bistable” and “bistability” are used herein in their conventional meaning in the art to refer to displays comprising display elements having first and second display states differing in at least one optical property, and such that after any given element has been driven, by means of an electrical addressing pulse of finite duration, to assume either its first or second display state, after the addressing pulse has terminated, that state will persist for at least several times, e.g., at least four times, the minimum duration of the addressing pulse required to change the state of the display element. It is shown in U.S. Pat. No. 7,170,670 that some particle-based electrophoretic displays capable of gray scale are stable, not only in their extreme black and white states, but also in their intermediate gray states, and the same is true of some other types of electro-optic displays. This type of display is properly called “multi-stable” rather than bistable, although for convenience the term “bistable” may be used herein to cover both bistable and multi-stable displays.

Several types of electro-optic displays are known. One type of electro-optic display is a rotating bichromal member type as described, e.g., in U.S. Pat. Nos. 5,808,783; 5,777,782; 5,760,761; 6,054,071 6,055,091; 6,097,531; 6,128,124; 6,137,467; and 6,147,791 (although this type of display is often referred to as a “rotating bichromal ball” display, the term “rotating bichromal member” is preferred as more accurate since in some of the patents mentioned above the rotating members are not spherical). Such a display uses a large number of small bodies (typically spherical or cylindrical) that have two or more sections with differing optical characteristics, and an internal dipole. These bodies are suspended within liquid-filled vacuoles within a matrix, the vacuoles being filled with liquid so that the bodies are free to rotate. The appearance of the display is changed by applying an electric field thereto, thus rotating the bodies to various positions and varying which of the sections of the bodies is seen through a viewing surface. This type of electro-optic medium is typically bistable.

Another type of electro-optic display uses an electrochromic medium, e.g., an electrochromic medium in the form of a nanochromic film comprising an electrode formed at least in part from a semi-conducting metal oxide and a plurality of dye molecules capable of reversible color change attached to the electrode; see, e.g., O'Regan, B., et al., Nature 1991, 353, 737; and Wood, D., Information Display, 18(3), 24 (March 2002). See also Bach, U., et al., Adv. Mater., 2002, 14(11), 845. Nanochromic films of this type are also described, e.g., in U.S. Pat. Nos. 6,301,038; 6,870.657; and 6,950,220. This type of medium is also typically bistable.

Particle-based electrophoretic displays, in which charged particles move through a suspending fluid under the influence of an electric field, are another type of electro-optic display. Such displays have been the subject of intense research and development for a number of years. Electrophoretic displays can have attributes of good brightness and contrast, wide viewing angles, state bistability, and low power consumption when compared with liquid crystal displays. Nevertheless, problems with the long-term image quality of these displays have prevented their widespread usage. For example, particles that make up electrophoretic displays can settle, resulting in inadequate service-life for these displays.

As noted above, electrophoretic media require the presence of a fluid. In most prior art electrophoretic media, this fluid is a liquid, but electrophoretic media can be produced using gaseous fluids; see, e.g., Kitamura, T., et al., “Electrical toner movement for electronic paper-like display”, IDW Japan, 2001, Paper HCS1-1, and Yamaguchi, Y., et al., “Toner display using insulative particles charged triboelectrically”, IDW Japan, 2001, Paper AMD4-4). See also U.S. Patent Application Publication No. 2005/0001810; European Patent Applications 1,462,847; 1,482,354; 1,484,635; 1,500,971; 1,501,194; 1,536,271; 1,542,067; 1,577,702; 1,577,703; and 1,598,694; and International Applications WO 2004/090626; WO 2004/079442; and WO 2004/001498. Such gas-based electrophoretic media appear to be susceptible to the same types of problems due to particle settling as liquid-based electrophoretic media, when the media are used in an orientation that permits such settling, e.g., in a sign where the medium is disposed in a vertical plane. Indeed, particle settling appears to be a more serious problem in gas-based electrophoretic media than in liquid-based ones, since the lower viscosity of gaseous suspending fluids as compared with liquid ones allows more rapid settling of the electrophoretic particles.

Numerous patents and applications assigned to or in the names of the Massachusetts Institute of Technology (MIT) and E Ink Corporation describe various technologies used in encapsulated electrophoretic and other electro-optic media. Such encapsulated media comprise numerous small capsules, each of which itself comprises an internal phase containing electrophoretically-mobile particles in a fluid medium, and a capsule wall surrounding the internal phase. Typically, the capsules are themselves held within a polymeric binder to form a coherent layer positioned between two electrodes. The technologies described in these patents and applications include:
(a) Electrophoretic particles, fluids and fluid additives: see, e.g., U.S. Pat. Nos. 7,002,728 and 7,679,814;
(b) Capsules, binders and encapsulation processes: see, e.g., U.S. Pat. Nos. 6,922,276 and 7,411,719;
(c) Microcell structures, wall materials, and methods of forming microcells: see, e.g., U.S. Pat. Nos. 7,072,095 and 9,279,906;
(d) Methods for filling and sealing microcells: see, e.g., U.S. Pat. Nos. 7,144,942 and 7,715,088;
(e) Films and sub-assemblies containing electro-optic materials: see, e.g., U.S. Pat. Nos. 6,982,178 and 7,839,564;
(f) Backplanes, adhesive layers and other auxiliary layers and methods used in displays: see, e.g., U.S. Pat. Nos. 7,116,318 and 7,535,624;
(g) Color formation color adjustment: see, e.g., U.S. Pat. Nos. 6,017,584; 6,545,797; 6,664,944; 6,788,452; 6,864,875; 6,914,714; 6,972,893; 7,038,656; 7,038,670; 7,046,228; 7,052,571; 7,075,502; 7,167,155; 7,385,751; 7,492,505; 7,667,684; 7,684,108; 7,791,789; 7,800,813; 7,821,702; 7,839,564; 7,910,175; 7,952,790; 7,956,841; 7,982,941; 8,040,594; 8,054,526; 8,098,418; 8,159,636; 8,213,076; 8,363,299; 8,422,116; 8,441,714; 8,441,716; 8,466,852; 8,503,063; 8,576,470; 8,576,475; 8,593,721; 8,605,354; 8,649,084; 8,670,174; 8,704,756; 8,717,664; 8,786,935; 8,797,634; 8,810,899; 8,830,559; 8,873,129; 8,902,153; 8,902,491; 8,917,439; 8,964,282; 9,013,783; 9,116,412; 9,146,439; 9,164,207; 9,170,467; 9,170,468; 9,182,646; 9,195,111; 9,199,441; 9,268,191; 9,285,649; 9,293,511; 9,341,916; 9,360,733; 9,361,836; 9,383,623; and 9,423,666; and U.S. Patent Application Publication Nos. 2008/0043318; 2008/0048970; 2009/0225398; 2010/0156780; 2011/0043543; 2012/0326957; 2013/0242378; 2013/0278995; 2014/0055840; 2014/0078576; 2014/0340430; 2014/0340736; 2014/0362213; 2015/0103394; 2015/0118390; 2015/0124345; 2015/0198858; 2015/0234250; 2015/0268531; 2015/0301246; 2016/0011484; 2016/0026062; 2016/0048054; 2016/0116816; 2016/0116818; and 2016/0140909;
(h) Methods for driving displays: see, e.g., U.S. Pat. Nos. 5,930,026; 6,445,489; 6,504,524; 6,512,354; 6,531,997; 6,753,999; 6,825,970; 6,900,851; 6,995,550; 7,012,600; 7,023,420; 7,034,783; 7,061,166; 7,061,662; 7,116,466; 7,119,772; 7,177,066; 7,193,625; 7,202,847; 7,242,514; 7,259,744; 7,304,787; 7,312,794; 7,327,511; 7,408,699; 7,453,445; 7,492,339; 7,528,822; 7,545,358; 7,583,251; 7,602,374; 7,612,760; 7,679,599; 7,679,813; 7,683,606; 7,688,297; 7,729,039; 7,733,311; 7,733,335; 7,787,169; 7,859,742; 7,952,557; 7,956,841; 7,982,479; 7,999,787; 8,077,141; 8,125,501; 8,139,050; 8,174,490; 8,243,013; 8,274,472; 8,289,250; 8,300,006; 8,305,341; 8,314,784; 8,373,649; 8,384,658; 8,456,414; 8,462,102; 8,514,168; 8,537,105; 8,558,783; 8,558,785; 8,558,786; 8,558,855; 8,576,164; 8,576,259; 8,593,396; 8,605,032; 8,643,595; 8,665,206; 8,681,191; 8,730,153; 8,810,525; 8,928,562; 8,928,641; 8,976,444; 9,013,394; 9,019,197; 9,019,198; 9,019,318; 9,082,352; 9,171,508; 9,218,773; 9,224,338; 9,224,342; 9,224,344; 9,230,492; 9,251,736; 9,262,973; 9,269,311; 9,299,294; 9,373,289; 9,390,066; 9,390,661; and 9,412,314; and U.S. Patent Application Publication Nos. 2003/0102858; 2004/0246562; 2005/0253777; 2007/0091418; 2007/0103427; 2007/0176912; 2008/0024429; 2008/0024482; 2008/0136774; 2008/0291129; 2008/0303780; 2009/0174651; 2009/0195568; 2009/0322721; 2010/0194733; 2010/0194789; 2010/0220121; 2010/0265561; 2010/0283804; 2011/0063314; 2011/0175875; 2011/0193840; 2011/0193841; 2011/0199671; 2011/0221740; 2012/0001957; 2012/0098740; 2013/0063333; 2013/0194250; 2013/0249782; 2013/0321278; 2014/0009817; 2014/0085355; 2014/0204012; 2014/0218277; 2014/0240210; 2014/0240373; 2014/0253425; 2014/0292830; 2014/0293398; 2014/0333685; 2014/0340734; 2015/0070744; 2015/0097877; 2015/0109283; 2015/0213749; 2015/0213765; 2015/0221257; 2015/0262255; 2015/0262551; 2016/0071465; 2016/0078820; 2016/0093253; 2016/0140910; and 2016/0180777 (these patents and applications may hereinafter be referred to as the MEDEOD (MEthods for Driving Electro-optic Displays) applications);
(i) Applications of displays: see, e.g., U.S. Pat. Nos. 7,312,784 and 8,009,348; and
(j) Non-electrophoretic displays: see, e.g., U.S. Pat. No. 6,241,921 and U.S. Patent Application Publication Nos. 2015/0277160, 2015/0005720, and 2016/0012710.

Many of the aforementioned patents and applications recognize that the walls surrounding the discrete microcapsules in an encapsulated electrophoretic medium could be replaced by a continuous phase, thus producing a so-called polymer-dispersed electrophoretic display, in which the electrophoretic medium comprises a plurality of discrete droplets of an electrophoretic fluid and a continuous phase of a polymeric material, and that the discrete droplets of electrophoretic fluid within such a polymer-dispersed electrophoretic display may be regarded as capsules or microcapsules even though no discrete capsule membrane is associated with each individual droplet; see, e.g., U.S. Pat. No. 6,866,760. Accordingly, for purposes of the present application, such polymer-dispersed electrophoretic media are regarded as sub-species of encapsulated electrophoretic media.

A related type of electrophoretic display is a so-called microcell electrophoretic display. In a microcell electrophoretic display, the charged particles and the fluid are not encapsulated within microcapsules, but instead are retained within a plurality of cavities formed within a carrier medium, typically a polymeric film. See, e.g., U.S. Pat. Nos. 6,672,921 and 6,788,449.

Another type of electro-optic display is an electro-wetting display developed by Philips and described in Hayes, R. A., et al., “Video-Speed Electronic Paper Based on Electrowetting”, Nature, 425, 383-385 (2003). It is shown in U.S. Pat. No. 7,420,549 that such electro-wetting displays can be made bistable.

Other types of electro-optic materials may also be used in various embodiments. Of particular interest, bistable ferroelectric liquid crystal displays (FLCs) are known in the art.

Although electrophoretic media are often opaque (since, e.g., in many electrophoretic media, the particles substantially block transmission of visible light through the display) and operate in a reflective mode, many electrophoretic displays can be made to operate in a so-called “shutter mode” in which one display state is substantially opaque and one is light-transmissive. See, e.g., the aforementioned U.S. Pat. Nos. 6,130,774 and 6,172,798, and U.S. Pat. Nos. 5,872,552; 6,144,361; 6,271,823; 6,225,971; and 6,184,856. Dielectrophoretic displays, which are similar to electrophoretic displays but rely upon variations in electric field strength, can operate in a similar mode; see, e.g., U.S. Pat. No. 4,418,346.

An encapsulated or microcell electrophoretic display typically does not suffer from the clustering and settling failure mode of traditional electrophoretic devices and provides further advantages, such as the ability to print or coat the display on a wide variety of flexible and rigid substrates. (Use of the word “printing” is intended to include all forms of printing and coating, including, but without limitation: pre-metered coatings such as patch die coating, slot or extrusion coating, slide or cascade coating, curtain coating; roll coating such as knife over roll coating, forward and reverse roll coating; gravure coating; dip coating; spray coating; meniscus coating; spin coating; brush coating; air knife coating; silk screen printing processes; electrostatic printing processes; thermal printing processes; ink jet printing processes; electrophoretic deposition; and other similar techniques.) Thus, the resulting display can be flexible. Further, because the display medium can be printed (using a variety of methods), the display itself can be made inexpensively.

An electro-optic display normally comprises a layer of electro-optic material and at least two other layers disposed on opposed sides of the electro-optic material, one of these two layers being an electrode layer. In most such displays both the layers are electrode layers, and one or both of the electrode layers are patterned to define the pixels of the display. In most electro-optic displays, at least one of the electrode layers is light-transmissive. In a passive matrix device, one electrode layer may be patterned into elongate row electrodes while the other electrode layer is patterned into elongate column electrodes running at right angles to the row electrodes, the pixels being defined by the intersections of the row and column electrodes. Alternatively, and more commonly, one electrode layer has the form of a single continuous (light-transmissive) electrode and the other electrode layer is patterned into a matrix of pixel electrodes, each of which defines one pixel of the display. In another type of electro-optic display intended for use with a stylus, print head, or similar movable electrode separate from the display, only one of the layers adjacent the electro-optic layer comprises an electrode, the layer on the opposed side of the electro-optic layer typically being a protective layer intended to prevent the movable electrode damaging the electro-optic layer.

The manufacture of a three-layer electro-optic display normally involves at least one lamination operation. For example, several of the aforementioned MIT and E Ink patents and applications describe a process for manufacturing an encapsulated electrophoretic display in which an encapsulated electrophoretic medium comprising capsules in a binder is coated on to a flexible substrate comprising indium-tin-oxide (ITO) or a similar conductive coating (which acts as an one electrode of the final display) on a plastic film (e.g., polyethylene terephthalate (PET)), the capsules/binder coating being subsequently dried to form a coherent layer of the electrophoretic medium firmly adhered to the substrate. Separately, a backplane containing an array of pixel electrodes and an appropriate arrangement of conductors to connect the pixel electrodes to drive circuitry is prepared. To form the final display, the substrate having the capsule/binder layer thereon is laminated to the backplane using a lamination adhesive. (A very similar process can be used to prepare an electrophoretic display usable with a stylus or similar movable electrode by replacing the backplane with a simple protective layer, such as a plastic film, over which the stylus or other movable electrode can slide.) In one form of such a process, the backplane is itself flexible and is prepared by printing the pixel electrodes and conductors on a plastic film or other flexible substrate. A lamination technique for mass production of displays by this process is roll-to-roll lamination using a lamination adhesive. Similar manufacturing techniques can be used with other types of electro-optic displays. For example, a microcell electrophoretic medium or a rotating bichromal member medium may be laminated to a backplane in substantially the same manner as an encapsulated electrophoretic medium.

As discussed in the aforementioned U.S. Pat. No. 6,982,178, many of the components used in solid electro-optic displays and the methods used to manufacture such displays are derived from technology used in liquid crystal displays (LCDs), which are also electro-optic displays, though using a liquid medium. However, the methods used for assembling LCDs cannot be used with solid electro-optic displays. LCDs are normally assembled by forming the backplane and front electrode on separate glass substrates, then adhesively securing these components together leaving a small aperture between them, placing the resultant assembly under vacuum, and immersing the assembly in a bath of the liquid crystal, so that the liquid crystal flows through the aperture between the backplane and the front electrode. Finally, with the liquid crystal in place, the aperture is sealed to provide the final display.

Segmented displays include an arrangement of display segments that can be individually controlled to render a desired image. In segmented electro-optic displays, the display segments can be formed in the backplane of the display, and are selectively driven to change the optical states of adjacent portions of the electro-optic medium.

Various embodiments disclosed herein relate to improved backplanes for segmented electro-optic displays and methods of manufacturing such backplanes. The backplanes can be laminated to a front plane laminate including an encapsulated electro-optic medium to produce the segmented electro-optic displays.

### SUMMARY OF THE INVENTION

A method is disclosed according to one aspect of the invention for manufacturing a backplane for a segmented electro-optic display. The method includes the steps of: (a) providing a laminate comprising an insulating layer having opposite first and second surfaces and a conductive metal layer having opposite first and second surfaces, wherein the second surface of the insulating layer is superposed on the first surface of the conductive metal layer; (b) applying laser energy from a first laser source passing through the insulating layer onto selected portions of the first surface of the conductive metal layer to cause adjacent portions of the insulating layer to be pyrolyzed to form conductive carbon regions; and (c) applying laser energy from a second laser source on the first surface of the insulating layer to pyrolyze selected portions of the first surface of the insulating layer into a plurality of conductive carbon segments electrically isolated from each other by other portions of the insulating layer, wherein the conductive carbon regions in the insulating layer form vias between each of the plurality of conductive carbon segments and one of the selected portions of the conductive metal layer.

A backplane for a segmented electro-optic display is disclosed in accordance with another aspect of the invention. The backplane comprises: (a) an insulating layer having opposite first and second surfaces; (b) a conductive metal layer having opposite first and second surfaces, wherein the second surface of the insulating layer is superposed on the first surface of the conductive metal layer; (c) a plurality of conductive carbon segments on the first surface of the insulating layer electrically isolated from each other by portions of the insulating layer and formed by applying laser energy from a second laser source on selected portions of the first surface of the insulating layer; and (d) conductive carbon vias in the insulating layer electrically connecting each of selected portions of the conductive metal layer to a different one of the conductive carbon segments, said conductive carbon vias formed by applying laser energy from a first laser source different from the second laser source on the first surface of the insulating layer, said laser energy from the first laser source passing through the insulating layer onto the selected portions of the first surface of the conductive metal layer to cause adjacent portions of the second surface of the insulating layer to pyrolyze to form said conductive carbon vias.

In accordance with one or more embodiments, the insulating layer comprises a polyimide layer, a Polyethersulfone layer, or a Polybenzimidazole layer.

In accordance with one or more embodiments, the insulating layer comprises a Kapton® polyimide film.

In accordance with one or more embodiments, the conductive metal layer comprises a copper layer, a silver layer, or an aluminum layer.

In accordance with one or more embodiments, the conductive metal layer comprises a pattern of traces.

In accordance with one or more embodiments, the second laser source comprises a CO2 laser.

In accordance with one or more embodiments, the second laser source emits a laser beam having a wavelength of about 9-11 μm.

In accordance with one or more embodiments, the first laser source comprises a Nd:YAG fiber laser.

In accordance with one or more embodiments, the first laser source emits a laser beam having a wavelength of about 1 μm.

In accordance with one or more embodiments, the insulating layer absorbs about 20% of the laser energy from the first laser source.

In accordance with one or more embodiments, the insulating layer has a thickness of at least 12 μm.

In accordance with one or more embodiments, the insulating layer has a thickness of about 12 μm to about 70 μm.

In accordance with one or more embodiments, the conductive metal layer has a thickness of at least 9 μm.

### BRIEF DESCRIPTION OF DRAWINGS

Additional details of one or more embodiments of the subject matter described in this specification are set forth in the accompanying drawings and the description below. Other features, aspects, and advantages of the subject matter will become apparent from the descriptions contained herein and the accompanying drawings. It should be stressed that the accompanying drawings are schematic and not to scale. In particular, for ease of illustration, the thicknesses of the various layers in the drawings do not correspond to their actual thicknesses. Also, the thicknesses of the various layers are out of scale relative to their lateral dimensions. Generally, elements of similar structures are annotated with like reference numerals for illustrative purposes throughout the drawings. However, the specific properties and functions of elements in different embodiments may not be identical. Further, the drawings are only intended to facilitate the description of the subject matter. The drawings do not illustrate every aspect of the described embodiments and do not limit the scope of the present disclosure or claims.

FIG. 1 is a schematic cross-section view showing an exemplary front plane laminate in accordance with the prior art.

FIG. 2 is a schematic diagram showing an exemplary electro-optic device in accordance with one or more embodiments.

FIG. 3 is a photograph showing an exemplary segmented electro-optic device in accordance with one or more embodiments.

FIG. 4 is a schematic cross-section view showing an exemplary backplane of a segmented electro-optic device in accordance with the prior art.

FIG. 5 is a schematic cross-section view showing an exemplary backplane of the segmented electro-optic device in accordance with one or more embodiments.

FIGS. 6A-6C schematically illustrate an exemplary process for forming the backplane of a segmented electro-optic device in accordance with one or more embodiments.

FIG. 7 is a schematic cross-section view showing an alternate exemplary backplane of a segmented electro-optic device in accordance with one or more embodiments.

FIG. 8 is a schematic cross-section view showing another exemplary backplane of a segmented electro-optic device in accordance with one or more embodiments.

FIG. 9 is a schematic diagram showing an exemplary conductive trace pattern in a backplane of a segmented electro-optic device in accordance with one or more embodiments.

### DETAILED DESCRIPTION

Various embodiments disclosed herein relate to backplanes with an integrated barrier in segmented electro-optic displays and methods of manufacturing such backplanes. The backplanes are laminated to a front plane laminate (“FPL”), which includes an encapsulated electro-optic medium, to produce segmented electro-optic displays.

The term “backplane” is used herein consistent with its conventional meaning in the art of electro-optic displays and in the aforementioned patents and published applications to mean a rigid or flexible material provided with one or more electrodes in an electro-optic display. The backplane may also be provided with electronics for addressing the display, or such electronics may be provided in a unit separate from the backplane. In flexible displays, it is desirable that the backplane provide sufficient barrier properties to prevent ingress of moisture and other contaminants through the non-viewing side of the display (the display is of course normally viewed from the side remote from the backplane).

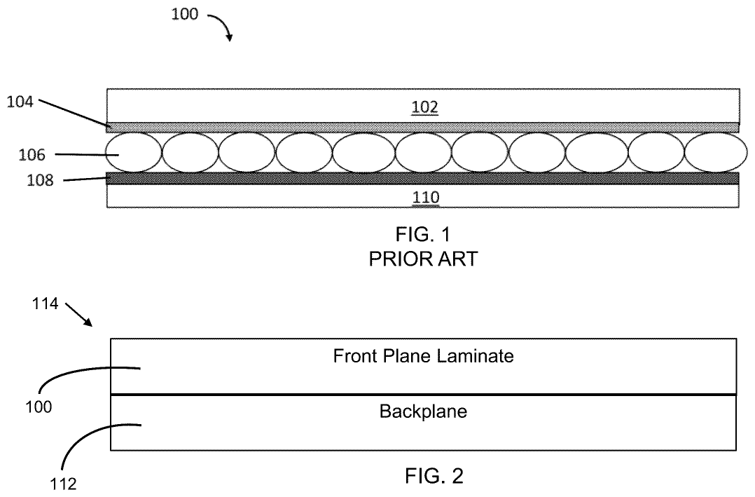

FIG. 1 schematically shows an exemplary front plane laminate (FPL) 100. As shown in FIG. 2, the FPL 100 can be laminated to a backplane 112 to produce an electro-optic display 114, e.g., a segmented electro-optic display, in accordance with one or more embodiments. The FPL 100 is similar to those described in U.S. Pat. No. 10,503,041, incorporated by reference herein. The FPL 100 includes, in order, a front plane light-transmissive substrate 102, a light-transmissive electrically-conductive layer 104 in contact with the inner surface of the front plane light-transmissive substrate 102, a layer of an electro-optic medium 106, an adhesive layer 108, and a release sheet 110. It is understood that in other FPL embodiments, an additional layer of adhesive may be disposed between the light-transmissive electrically-conductive layer 104 and the layer of an electro-optic medium 106 (not shown in FIG. 1).

In many applications, front plane light-transmissive substrate 102 comprises a PET layer, and the light-transmissive electrically-conductive layer 104 comprises indium tin oxide (ITO). Such materials are commercially available in large rolls, e.g., from Saint-Gobain. The light-transmissive electrically-conductive layer 104 is applied to the light-transmissive substrate 102, which is usually flexible, in the sense that the substrate can be manually wrapped around a drum, e.g., 10 inches (254 mm) in diameter without permanent deformation.

The term “light-transmissive” is used herein consistent with its conventional meaning in the art of electro-optic displays and in the aforementioned patents and published applications to mean that the layer thus designated transmits sufficient light to enable an observer, looking through that layer, to observe the change in display states of the electro-optic medium, which will normally be viewed through the electrically-conductive layer 104 and adjacent substrate 102. In instances where the electro-optic medium 106 displays a change in reflectivity at non-visible wavelengths, the term “light-transmissive” should of course be interpreted to refer to transmission of the relevant non-visible wavelengths. The substrate 102 may be manufactured from a glass or a polymeric film, e.g., PET, and may have a thickness in the range from about 20 μm to about 650 μm, more typically about 50 μm to about 250 μm. The electrically-conductive layer 104 is typically a thin layer of a so-called “transparent conducting oxide” such as aluminum oxide, zinc oxide, indium zinc oxide, or indium-tin-oxide, or the electrically-conductive layer 104 may include a conductive polymer, such as poly(3,4-ethylenedioxythiophene) (PEDOT). The design may also include hybrid materials, such as a combination of conductive polymers and conducting oxides, or the design may also include dilute amounts of conductive fillers, such as silver whiskers or flakes, or exotic materials such as nanotubes and graphene. In some embodiments, the substrate 102 could be a rigid light-transmissive material such as glass or transparent polycarbonate or acrylic.

Typically, a coating of the electro-optic medium 106, which can be switched between optical states, is applied over the electrically-conductive layer 104, such that the electro-optic medium 106 is in close proximity to the electrically-conductive layer 104. The electro-optic medium will typically feature an electrophoretic material including a plurality of electrically-charged particles disposed in a fluid and capable of moving through the fluid under the influence of an electric field. The electrophoretic material can be selected such that the front panel laminate interchangeably and reversibly achieves different states when an appropriate electric field is applied, e.g., the electrophoretic medium may switch between clear and opaque, or color 1 and color 2, or clear and color 1 and color 2.

In some embodiments, the electro-optic medium may be in the form of an oppositely charged dual particle encapsulated medium. Such encapsulated media includes numerous small capsules, each of which itself comprises an internal phase containing electrophoretically-mobile particles suspended in a liquid suspension medium, and a capsule wall surrounding the internal phase. Typically, the capsules are themselves held within a polymeric binder to form a coherent layer. When the coherent layer is positioned between two electrodes the optical states can be reversed with the presentation of a suitable electric field. The suspension medium may contain a hydrocarbon-based liquid in which are suspended negatively charged white particles and positively charged black particles. In such an embodiment, upon application of an electrical field across the electro-optic medium, the white particles move to the positive electrode and the black particles move to the negative electrode, e.g., so that the electro-optic medium 106 appears, to an observer viewing the display through the substrate 102, white or black depending upon whether the electrically-conductive layer 104 is positive or negative relative to the backplane at any point within the final display. The electro-optic medium 106 may alternatively comprise a plurality of colored particles in addition to black and/or white particles, each color having its respective charge polarity and strength. While not shown in the figures, it is understood that a microcell-type FPL of the type discussed above could also be used with backplanes of the invention.

A layer of lamination adhesive 108 is coated over the electro-optic medium layer 106, and a release sheet 110 is applied over the adhesive layer 108. The release sheet 110 may be of any known type, provided of course that it does not contain materials that adversely affect the properties of the electro-optic medium. Numerous suitable types of release sheets will be known to those skilled in the art. Common release sheets comprise a substrate such as paper or a plastic film, for example a PET film that is approximately about 150 μm to about 200 μm in thickness and coated with a low surface energy material, e.g., a silicone. In some instances, the release sheet is metalized to allow for application of a potential across the electro-optic medium so that functionality can be assessed during assembly of a downstream product.

Turning now to FIG. 2, the electro-optic display 114 is assembled by removing the release sheet 110 on the FPL 100 and contacting the adhesive layer 108 with the backplane 112 under conditions effective to cause the adhesive layer 108 to adhere to the backplane 112, thereby securing the adhesive layer 108, layer of electro-optic medium 106, and light-transmissive electrically-conductive layer 104 to the backplane 112. The FPL 100 can be cut larger than the final display size and could even be a continuous sheet as in a roll-to-roll process. This allows for coarse tolerances in alignment of the FPL 100 and backplane 112, which is especially helpful for large displays. Once laminated, the display can be cut to its final size, potentially using alignment marks or pins on the backplane to allow for precisely aligning the cut to the backplane.

The lamination of the FPL 100 to the backplane 112 may advantageously be carried out by vacuum lamination. Vacuum lamination is effective in expelling air from between the two materials being laminated, thus avoiding unwanted air bubbles in the final display; such air bubbles may introduce undesirable artifacts in the images produced on the display. However, vacuum lamination of the two parts of an electro-optic display 114 in this manner may impose stringent requirements upon the lamination adhesive used, especially in the case of a display using an encapsulated electrophoretic medium. The lamination adhesive 108 should have sufficient adhesive strength to bind the electro-optic layer 106 to the backplane 112, and in the case of an encapsulated electrophoretic medium, the adhesive 108 should also have sufficient adhesive strength to mechanically hold the capsules together. The adhesive 108 is preferably chemically compatible with all the other materials in the display 114. If the electro-optic display 114 is to be of a flexible type, the adhesive 108 should have sufficient flexibility not to introduce defects into the display when the display is flexed. The lamination adhesive 108 should have adequate flow properties at the lamination temperature to ensure high quality lamination. Furthermore, the lamination temperature is preferably as low as possible. One example of a useful lamination adhesive that may be incorporated in the various embodiments is an aqueous polyurethane dispersion known as a “TMXDI/PPO” dispersion, as described in U.S. Pat. No. 7,342,068, which is incorporated by reference in its entirety.

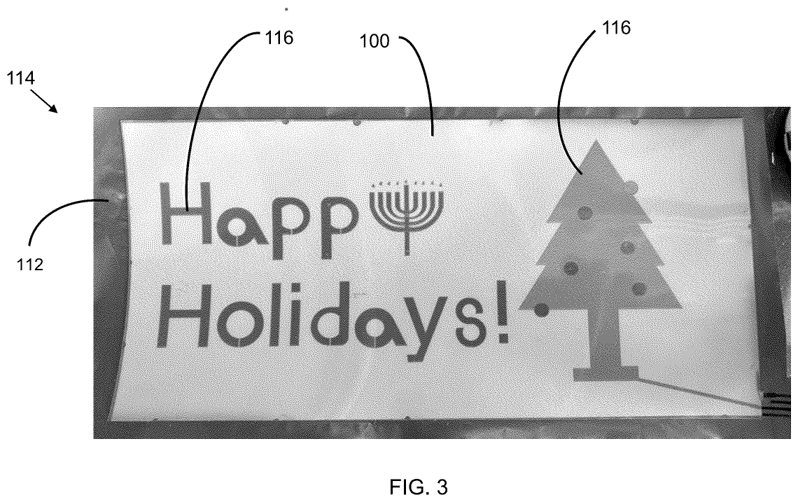

FIG. 3 is a photograph showing one example of a segmented electro-optic device 114 in accordance with one or more embodiments. The FPL 100 is laminated on a backplane 112. In this example, an image is rendered on the device 114 comprising an arrangement of image elements 116, including a Christmas tree, a Menorah, and text. The image elements 116 correspond to and are aligned with similarly shaped display segments formed in a segmented conductive layer in the backplane 112 as discussed below.

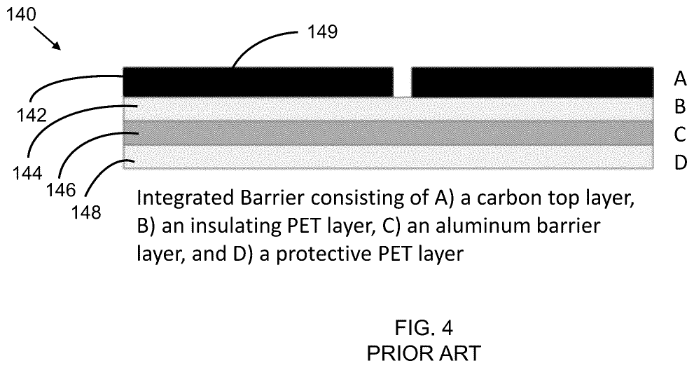

FIG. 4 is a schematic cross-section view showing an exemplary backplane 140 of a segmented electro-optic device, including a moisture barrier layer, in accordance with the prior art. The backplane 140 includes, in order, a conductive carbon top layer 142, a PET insulating layer 144, an aluminum barrier layer 146, and an additional PET (protective) layer 148. The conductive carbon top layer 142 is ablated with a fiber laser to form a plurality of display segment shapes 149, which are connected to electrical trace connections in the top layer. Backplanes of this type are predominantly used in single layered segmented designs, i.e., both the display segment shapes and the electrical trace connections are in in one layer. However, a multilayer design in which the display segment shapes and the electrical trace connections are in in separate layers would be preferable over a single layer design because it has fewer design constraints. For instance, traces would not have to be routed visibly between display segments. In addition, display segments located distantly from an edge connector of the device leading to a display controller could be connected by more conductive metal traces in a multilayer design taking more efficient paths rather than lengthy, lower conductive carbon traces. Making a two layer segmented display backplane of this type to separate the display segment shapes from the electrical trace connections would, however, ordinarily require adding multiple steps to pattern and apply additional insulating and conductive layers.

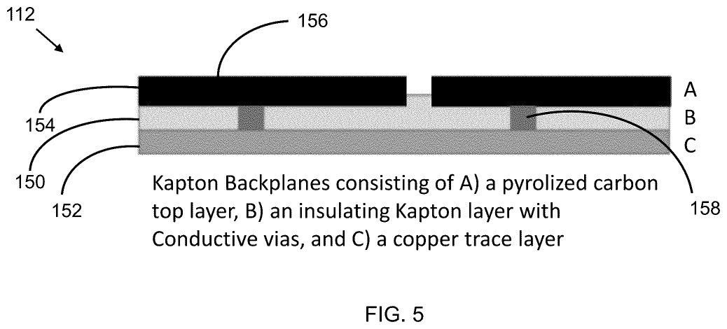

FIG. 5 is a schematic cross-section view showing an exemplary backplane 112 for a segmented electro-optic device 114 in accordance with one or more embodiments. The backplane 112 includes an insulating layer 150 and a conductive metal layer 152. A conductive carbon top layer 154 comprising a plurality of display segment shapes 156 is formed in the insulating layer 150. The display segment shapes 156 are electrically isolated from one another. Vias 158 are formed in the insulating layer 150 electrically connecting each display segment 156 to the conductive metal layer 152. The display segment shapes 156 are thus located in a separate layer from the electrical trace connections. As a result, traces are not visibly routed between display segments 156. In addition, the conductive metal layer 152 more efficiently connects display segments 156 located distantly from an edge connector of the device leading to the display controller than conductive carbon traces.

In one or more embodiments, the insulating layer 150 comprises a polyimide layer, preferably a Kapton® polyimide film available from DuPont de Nemours, Inc. The polyimide film preferably has a thickness of at least 12 μm. In one or more embodiments, the polyimide film has a thickness between about 12 μm and about 70 μm.

In other embodiments, the insulating layer 150 can comprise Polyethersulfone, Polybenzimidazole, and similar materials.

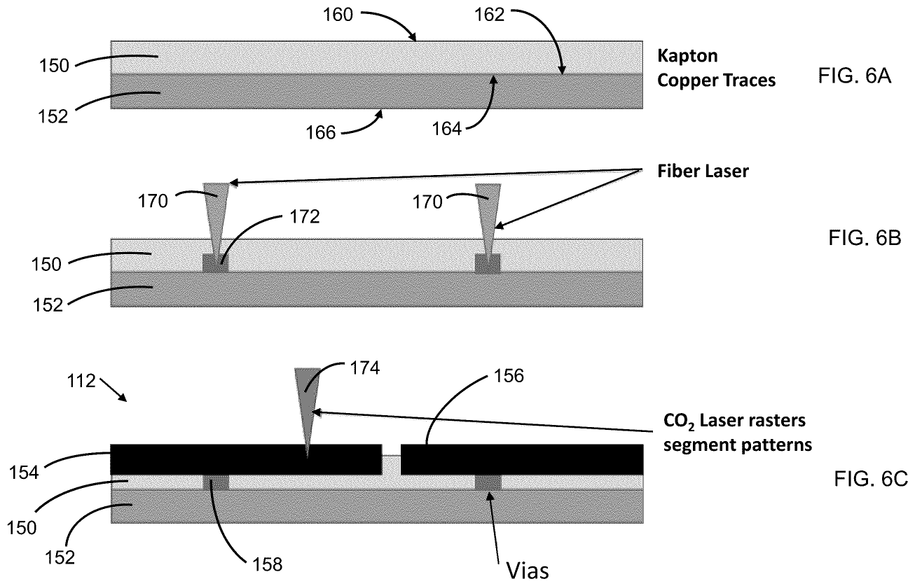

FIGS. 6A-6C schematically illustrate an exemplary process for manufacturing the backplane 112 of the segmented electro-optic device 114 in accordance with one or more embodiments.

As shown in FIG. 6A, the backplane 112 is constructed from a laminate comprising the insulating layer 150, which has opposite first and second surfaces 160, 162, and the conductive metal layer 152, which has opposite first and second surfaces 164, 166. The second surface 162 of the insulating layer 150 is superposed on the first surface 164 of the conductive metal layer 152.

As shown in FIG. 6B, laser energy is applied from a laser source 170 within a range of wavelengths that substantially pass through the insulating layer 150 onto selected portions of the first surface 164 of the conductive metal layer 152 to cause adjacent portions 172 of the insulating layer 150 to be pyrolyzed to form the conductive carbon vias 158.

As shown in FIG. 6C, laser energy from a second laser source 174 is applied on the first surface 160 of the insulating layer 150 to pyrolyze selective portions of the first surface 160 of the insulating layer 150 into the plurality of conductive carbon segments 156 electrically isolated from each other by other portions of the insulating layer 150. The vias 158 electrically connect each of the carbon segments 156 to the conductive metal layer 152.

In one or more embodiments, the laser source 174 used to pyrolyze portions of the insulating layer 150 to form the conductive carbon segments 156 comprises a CO₂ laser. In one or more embodiments, the CO₂ laser emits a laser beam having a wavelength of about 9-11 μm. Use of a CO₂ laser to pyrolize the insulating layer 150, especially a Kapton® polyimide film, enables the insulating gaps between the conductive carbon segments 156 to be made relatively small compared to other processes.

In one or more embodiments, the laser source 170 forming the vias 158 in the insulating layer 150 comprises a neodymium-doped yttrium aluminum garnet (Nd:YAG) fiber laser that emits light with a typical wavelength of about 1 μm (between about 940 nm and about 1440 nm).

Use of a fiber laser 170 allows the vias to be formed from the bottom up, i.e., from the conductive metal layer 152 to the conductive carbon segments 156. It is believed that the insulating layer 150 is pyrolized to form the vias 158 by a combination of the heating of the conductive metal layer 152 by the fiber laser 170 and reflection of the fiber laser beam by the conductive metal layer 152 back into the insulating layer 150 such that the focal point of the laser beam is within the insulating layer 150.

In addition to the creation of vias 158, the fiber laser 174 can also be used to ablate or pyrolize any other materials on the back of the insulating layer 150, if desired.

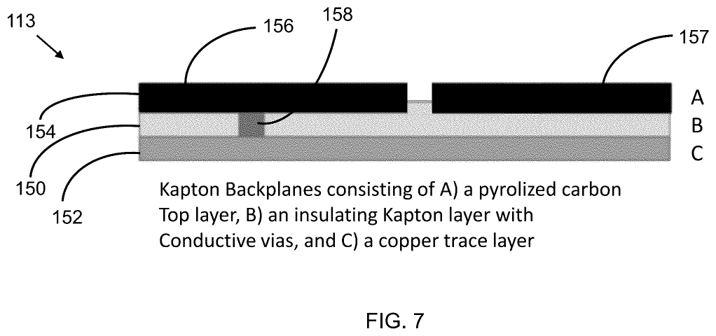

FIG. 7 is a schematic cross-section view showing an exemplary backplane 113 for a segmented electro-optic device 114 in accordance with one or more alternate embodiments. The backplane 113 includes an insulating layer (e.g., Kapton® polyimide film) 150 and a conductive metal (e.g., copper) layer 152. A conductive carbon top layer 154 comprising a plurality of display segment shapes 156, 157 is formed in the insulating layer 150. The display segment shapes 156, 157 are electrically isolated from one another. A via 158 is formed in the insulating layer 150 electrically connecting the display segment 156 to the conductive metal layer 152. However, display segment 157 does not have an associated via and is not electrically connected to the conductive metal layer 152. The display segment 157 may include a conductive carbon trace on the insulating layer 150 leading to an edge connector (not shown), which can be connected to a display controller (not shown). In this way, the display controller can separately drive display segment 157 and display segment 156 to achieve different optical states in corresponding sections of the FPL 100. For example, in FIG. 3, the display segment generating the Christmas tree image is connected by a trace to the edge connector while the other image elements are connected to the connector via the conductive metal layer 152. In this way, the Christmas tree can be rendered with a different color than the other image elements.

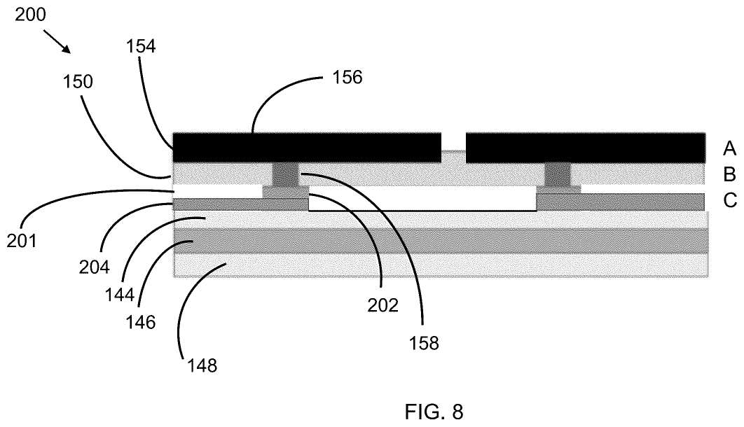

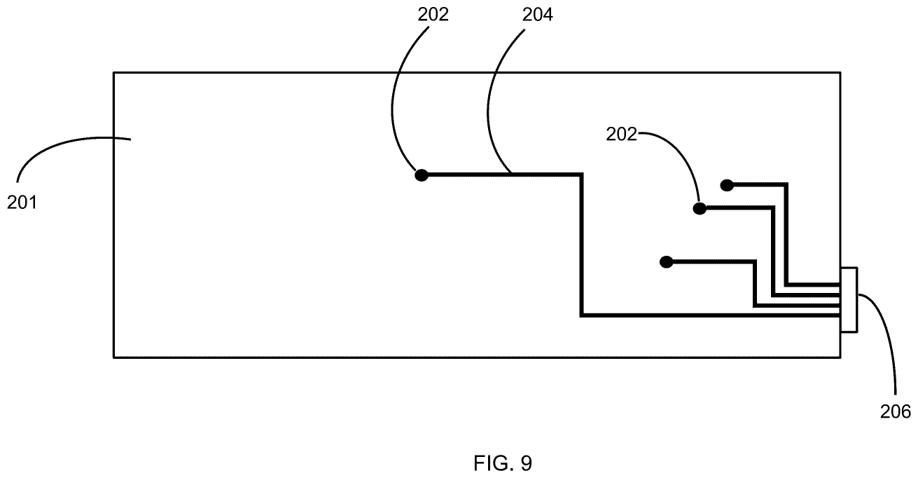

FIG. 8 is a schematic cross-section view showing an exemplary backplane 200 for a segmented electro-optic device 114 in accordance with one or more alternate embodiments. The backplane 200 includes, in order, a conductive carbon top layer 154, an insulating layer (e.g., Kapton® polyimide film) 150, a conductive metal trace layer 201 (shown, e.g., in FIG. 9), a PET insulating layer 144, an aluminum barrier layer 146, and an additional protective PET layer 148. The conductive carbon top layer 154 comprises a plurality of display segment shapes 156 formed in the insulating layer 150. The display segment shapes 156 are electrically isolated from one another. Vias 158 are formed in the insulating layer 150 (e.g., using the processes shown in FIGS. 6A-6C) electrically connecting each of the display segments 156 to the conductive metal trace layer 201.

FIG. 9 shows a simple example of the conductive metal trace layer 201. The conductive metal trace layer 201 comprises a plurality of electrodes 202 (comprising, e.g., copper, silver, or aluminum targets) connected to conductors 204 that extend to the edge of the backplane 200 to an electrical connector 206. The connector 206 can be connected to a display controller (not shown). The display controller can selectively control voltages applied to the conductors 204 to individually drive each of the display segments 156 in order to change the optical states of adjacent corresponding portions of the electro-optic medium in the FPL 100. In this way, it is possible to display different colors for each of the display segments.

The processes described above simplify the production of multilayer segmented displays and enable rapid formation of the conductive carbon segments 156 and the vias 158 in the backplane 112 using two lasers, which can be in one machine. By way of example, the process can be performed using a Speedy Flexx™ laser system available from Trotec Laser GmbH, which integrates CO₂ and fiber laser sources in one machine.

It will be apparent to those skilled in the art that numerous changes and modifications can be made in the specific embodiments of the invention described above without departing from the scope of the invention. Accordingly, the whole of the foregoing description is to be interpreted in an illustrative and not in a limitative sense.

1. A method of manufacturing a backplane for a segmented electro-optic display, comprising:
providing a laminate comprising an insulating layer having opposite first and second surfaces and a conductive metal layer having opposite first and second surfaces, wherein the second surface of the insulating layer is superposed on the first surface of the conductive metal layer;
applying laser energy from a first laser source passing through the insulating layer onto selected portions of the first surface of the conductive metal layer to cause adjacent portions of the insulating layer to be pyrolyzed to form conductive carbon regions; and
applying laser energy from a second laser source on the first surface of the insulating layer to pyrolyze selected portions of the first surface of the insulating layer into a plurality of conductive carbon segments electrically isolated from each other by other portions of the insulating layer, wherein the conductive carbon regions in the insulating layer form vias between each of the plurality of conductive carbon segments and the conductive metal layer.

2. The method of claim 1, further comprising applying laser energy from the second laser source to pyrolyze one or more additional selected portions of the first surface of the insulating layer into at least one additional conductive carbon segment electrically isolated from the plurality of conductive carbon segments and from the conductive metal layer, said at least one additional conductive carbon segment including a trace.

3. The method of claim 1, wherein the insulating layer comprises a polyimide layer, a Polyethersulfone layer, or a Polybenzimidazole layer.

4. The method of claim 1, wherein the conductive metal layer comprises a pattern of traces.

5. The method of claim 1, wherein the second laser source comprises a CO₂ laser.

6. The method of claim 1, wherein the second laser source emits a laser beam having a wavelength of about 9-11 μm.

7. The method of claim 1, wherein the first laser source comprises a Nd:YAG fiber laser.

8. The method of claim 1, wherein the first laser source emits a laser beam having a wavelength of about 1 μm.

9. The method of claim 1, wherein the insulating layer absorbs about 20% of the laser energy from the first laser source.

10. The method of claim 1, wherein the insulating layer has a thickness of at least 12 μm.

11. The method of claim 1, wherein the conductive metal layer has a thickness of at least 9 μm.

12. A backplane for a segmented electro-optic display, comprising:
an insulating layer having opposite first and second surfaces;
a conductive metal layer having opposite first and second surfaces, wherein the second surface of the insulating layer is superposed on the first surface of the conductive metal layer;
a plurality of conductive carbon segments on the first surface of the insulating layer electrically isolated from each other by portions of the insulating layer and formed by applying laser energy from a second laser source on selected portions of the first surface of the insulating layer; and
conductive carbon vias in the insulating layer electrically connecting each of selected portions of the conductive metal layer to a different one of the conductive carbon segments, said conductive carbon vias formed by applying laser energy from a first laser source different from the second laser source on the first surface of the insulating layer, said laser energy from the first laser source passing through the insulating layer onto the selected portions of the first surface of the conductive metal layer to cause adjacent portions of the second surface of the insulating layer to pyrolyze to form said conductive carbon vias.

13. The backplane of claim 12, further comprising at least one additional conductive carbon segment electrically isolated from the plurality of conductive carbon segments and from the conductive metal layer, said at least one additional conductive carbon segment formed by applying laser energy from the second laser source to pyrolyze one or more selected portions of the first surface of the insulating layer, wherein said at least one additional conductive carbon segment including a trace.

14. The backplane of claim 12, wherein the insulating layer comprises a polyimide layer, a Polyethersulfone layer, or a Polybenzimidazole layer.

15. The backplane of claim 12, wherein the conductive metal layer comprises a pattern of traces.

16. The backplane of claim 12, wherein the second laser source comprises a CO₂ laser.

17. The backplane of claim 12, wherein the second laser source emits a laser beam having a wavelength of about 9-11 μm.

18. The backplane of claim 12, wherein the first laser source comprises a Nd:YAG fiber laser.

19. The backplane of claim 12, wherein the first laser source emits a laser beam having a wavelength of about 1 μm.

20. The backplane of claim 12, wherein the insulating layer absorbs about 20% of the laser energy from the first laser source.

21. The backplane of claim 12, wherein the insulating layer has a thickness of at least 12 μm.

22. The backplane of claim 12, wherein the conductive metal layer has a thickness of at least 9 μm.

23. The backplane of claim 12, wherein the backplane is configured to be secured to a front plane laminate comprising a light-transmissive electrically-conductive layer and a layer of an encapsulated electro-optic medium in electrical contact with the electrically-conductive layer; wherein the layer of the encapsulated electro-optic medium is adapted to be superposed on the first surface of the insulating layer of the backplane on the conductive carbon segments.

24. An electro-optic display comprising the backplane of claim 12 secured to a front plane laminate.

25. The electro-optic display of claim 24, wherein the front plane laminate comprises a light-transmissive electrically-conductive layer and a layer of an encapsulated electro-optic medium disposed between the light-transmissive electrically-conductive layer and the backplane.

26. The electro-optic display of claim 24, wherein the electro-optic display is flexible.
